(19) United States
(12) Patent Application Publication
(10) Pub. No.: US 2025/0252407 A1
(43) Pub. Date: Aug. 7, 2025

(54) ABNORMALITY DETERMINATION DEVICE

(71) Applicant: IHI Corporation, Tokyo (JP)

(72) Inventors: Hiroaki HAYASE, Tokyo (JP); Hirotaka KAWABE, Tokyo (JP); Kiminori SATO, Tokyo (JP)

(21) Appl. No.: 19/185,268

(22) Filed: Apr. 22, 2025

Related U.S. Application Data
(63) Continuation of application No. PCT/JP2023/035616, filed on Sep. 29, 2023.

(30) Foreign Application Priority Data
Feb. 22, 2023 (JP) 2023-025851

(51) Int. Cl. G06Q 10/20; F23K 1/00; G01F 1/34; G01R 19/00

(52) U.S. Cl. CPC G06Q 10/20; F23K 1/00; G01F 1/34; G01R 19/0092; F23K 2201/1006

(57) ABSTRACT

An abnormality determination device determines whether or not there is an abnormality in a pulverizer that pulverizes solid fuel and supplies the solid fuel to a boiler of a thermal power plant. The abnormality determination device includes a data acquisition unit configured to acquire operation data indicating an operation state of the pulverizer, and an abnormality determination unit configured to determine whether or not there is an abnormality in the pulverizer based on whether or not the acquired operation data falls within a predetermined range.

### CROSS-REFERENCE TO RELATED APPLICATIONS

This application is a continuation application of PCT Application No. PCT/JP2023/035616, filed on Sep. 29, 2023, which claims the benefit of priority from Japanese Patent Application No. 2023-025851, filed on Feb. 22, 2023. The entire contents of which are incorporated herein by reference.

### BACKGROUND

The present disclosure relates to an abnormality determination device that determines whether or not there is an abnormality in a pulverizer.

There is a pulverizer that pulverizes solid fuel supplied to a boiler of a thermal power plant. In such a pulverizer, due to various reasons, it may become impossible to properly pulverize the solid fuel. In this case, an excessive amount of solid fuel may accumulate (remain) in the pulverizer. However, the solid fuel is pulverized in the housing of the pulverizer, so it is difficult to directly visually observe a accumulation (retention) state of the solid fuel in the pulverizer. For this reason, for example, Japanese Unexamined Patent Publication No. 2022-41973 describes a device that determines an abnormality in a pulverizer using operation data of a boiler, etc.

The device described in Japanese Unexamined Patent Publication No. 2022-41973 uses the operation data of the boiler which is a different device from the pulverizer to determine whether or not there is an abnormality in the pulverizer. However, it is considered that the change in the state of the pulverizer is not appropriately reflected in the operation data of the boiler. For this reason, the present disclosure describes an abnormality determination device which may be possible to more accurately determine whether or not there is an abnormality in the pulverizer.

### SUMMARY

An aspect of the present disclosure is an abnormality determination device for determining whether or not there is an abnormality in a pulverizer that pulverizes solid fuel and supplies the solid fuel to a boiler of a thermal power plant. The abnormality determination device includes a data acquisition unit configured to acquire operation data indicating an operation state of the pulverizer, and an abnormality determination unit configured to determine whether or not there is an abnormality in the pulverizer based on the acquired operation data.

According to an aspect of the present disclosure, it may be possible to more accurately determine whether or not there is an abnormality in a pulverizer using operation data of the pulverizer.

### BRIEF DESCRIPTION OF THE DRAWINGS

FIG. 1 is a diagram illustrating an example of a schematic configuration of a maintenance management system for a thermal power plant including an abnormality determination device.

FIG. 2 is a schematic diagram illustrating an example of the internal configuration of a pulverizer.

The top portion of FIG. 3A illustrates the distribution of a first index. A bottom portion of FIG. 3A illustrates time-series data of a shift amount of the first index. The top portion of FIG. 3B illustrates the distribution of a second index. A bottom portion of FIG. 3B illustrates time-series data of a shift amount of the second index.

The top portion of FIG. 4A illustrates the distribution of a third index. A bottom portion of FIG. 4A illustrates time-series data of a shift amount of the third index. The top portion of FIG. 4B illustrates the distribution of a fourth index. A bottom portion of FIG. 4B illustrates time-series data of a shift amount of the fourth index.

### DETAILED DESCRIPTION

An aspect of the disclosure is an abnormality determination device configured to determine whether or not there is an abnormality in a pulverizer that pulverizes solid fuel and supplies the solid fuel to a boiler of a thermal power plant. The abnormality determination device includes a data acquisition unit that acquires operation data indicating an operation state of the pulverizer, and an abnormality determination unit that determines whether or not there is an abnormality in the pulverizer based on the acquired operation data.

In this abnormality determination device, the abnormality determination unit determines whether or not there is an abnormality based on the operation data of the pulverizer in which changes in the state of the pulverizer readily appear. In this way, the abnormality determination device may more accurately determine whether or not there is an abnormality in the pulverizer using the operation data of the pulverizer.

The abnormality determination device may further include an index calculation unit that calculates an index indicating a correlation between two mutually different pieces of operation data acquired by the data acquisition unit. The abnormality determination unit may determine that there is an abnormality in the pulverizer when the calculated index falls outside a predetermined index range. In this case, the abnormality determination device may more accurately determine whether or not there is an abnormality in the pulverizer using an index indicating a correlation between two pieces of operation data.

The abnormality determination device may further include an index calculation unit that calculates a plurality of indices each indicating a correlation between two mutually different pieces of operation data acquired by the data acquisition unit. The plurality of calculated indices are different from each other in terms of a combination of two pieces of operation data used to calculate each index. The abnormality determination unit determines whether or not the index falls outside a predetermined index range for each of the plurality of indices. The abnormality determination unit may determine that there is an abnormality in the pulverizer when the number of indices out of the index range among the plurality of indices is equal to or greater than a predetermined reference number. In this case, the abnormality determination device may more accurately determine whether or not there is an abnormality in the pulverizer using a plurality of indices each indicating a correlation between pieces of the operation data.

The abnormality determination device may further include an index calculation unit that calculates a plurality of indices each indicating a correlation between two mutually different pieces of operation data acquired by the data acquisition unit. The plurality of calculated indices are different from each other in terms of a combination of two pieces of operation data used to calculate each index. The abnormality determination unit calculates an abnormality degree for each of the plurality of indices based on a shift (deviation) amount between an index reference value predetermined for each index and the index. The abnormality determination unit may determine that there is an abnormality in the pulverizer when a total value of a plurality of abnormality degrees calculated for each index exceeds a predetermined reference total value. In this case, the abnormality determination device may more accurately determine whether or not there is an abnormality in the pulverizer using the total value of the abnormality degrees of each of the plurality of indices.

In the abnormality determination device, the operation data may be at least any one of a flow rate of supplied air supplied into the pulverizer to deliver powder of solid fuel pulverized in the pulverizer out of the pulverizer by airflow, a flow damper opening of a flow damper that controls a flow rate of supplied air, a supply amount of solid fuel supplied to the pulverizer, a pressure difference between pressure of supplied air and pressure of delivered air delivered from the pulverizer to pump (deliever) powder using an airflow, and a current value of power supplied to an electric motor that drives a movable portion installed in the pulverizer to pulverize solid fuel. In this case, the abnormality determination device may accurately determine whether or not there is an abnormality in the pulverizer based on the operation data related to the pulverizer.

Hereinafter, examples of the disclosure will be described with reference to the drawings. It should be noted that, in each drawing, the same or corresponding elements are denoted by the same reference numerals, and duplicated description will be omitted.

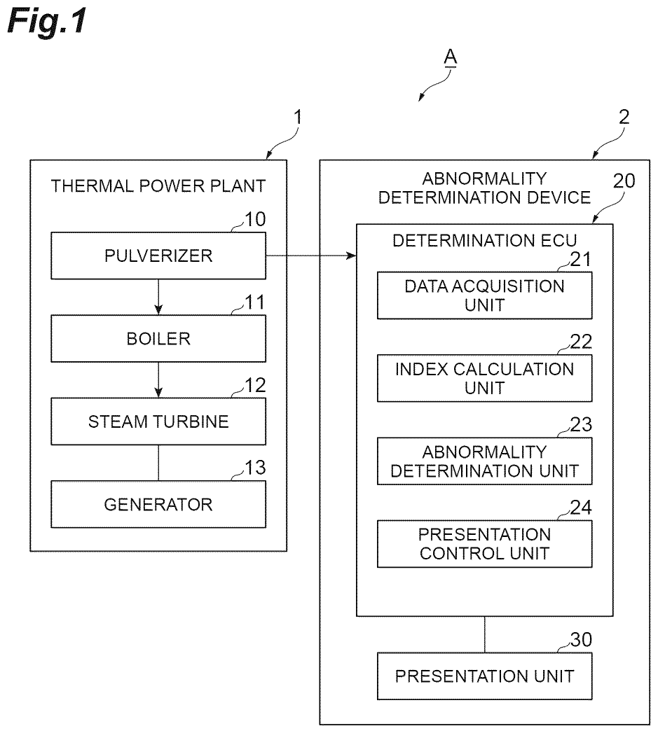

As illustrated in FIG. 1, a maintenance management system A includes a thermal power plant 1 and an abnormality determination device 2. The thermal power plant 1 generates electricity using heat generated by burning solid fuel. The solid fuel may be, for example, coal, biomass fuel, etc. The thermal power plant 1 includes a pulverizer 10, a boiler 11, a steam turbine 12, and a generator 13. The pulverizer 10 pulverizes the solid fuel and supplies the solid fuel to the boiler 11. The boiler 11 burns the pulverized solid fuel to generate steam. The steam generated by the boiler 11 is sent to the steam turbine 12 to drive the steam turbine 12. The generator 13 is connected to the steam turbine 12. The generator 13 generates electricity by driving the steam turbine 12 using the steam. It should be noted that, although illustration and description are omitted, the thermal power plant 1 includes various devices such as a device for purifying flue gas.

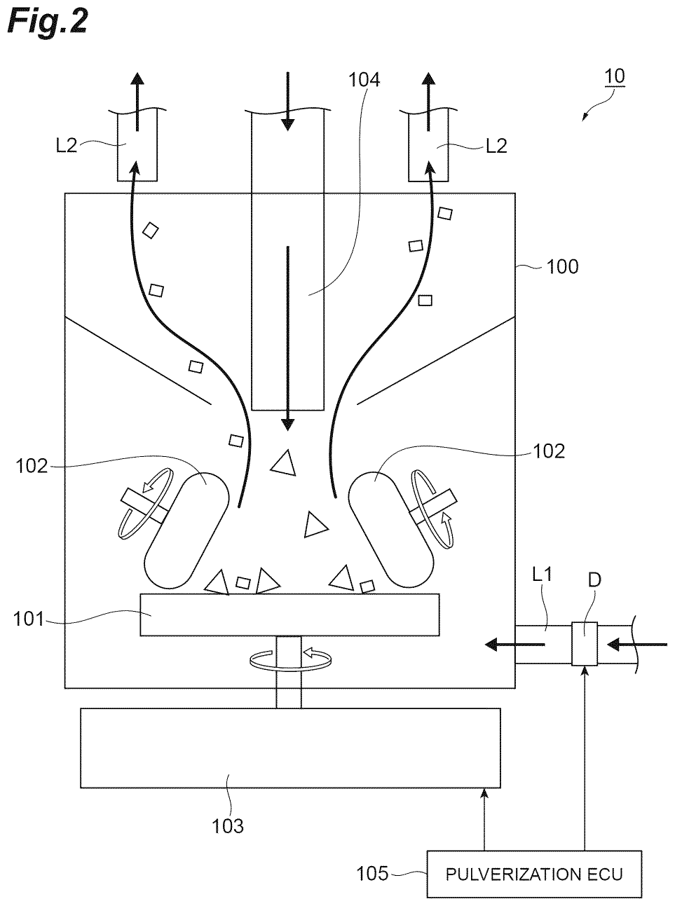

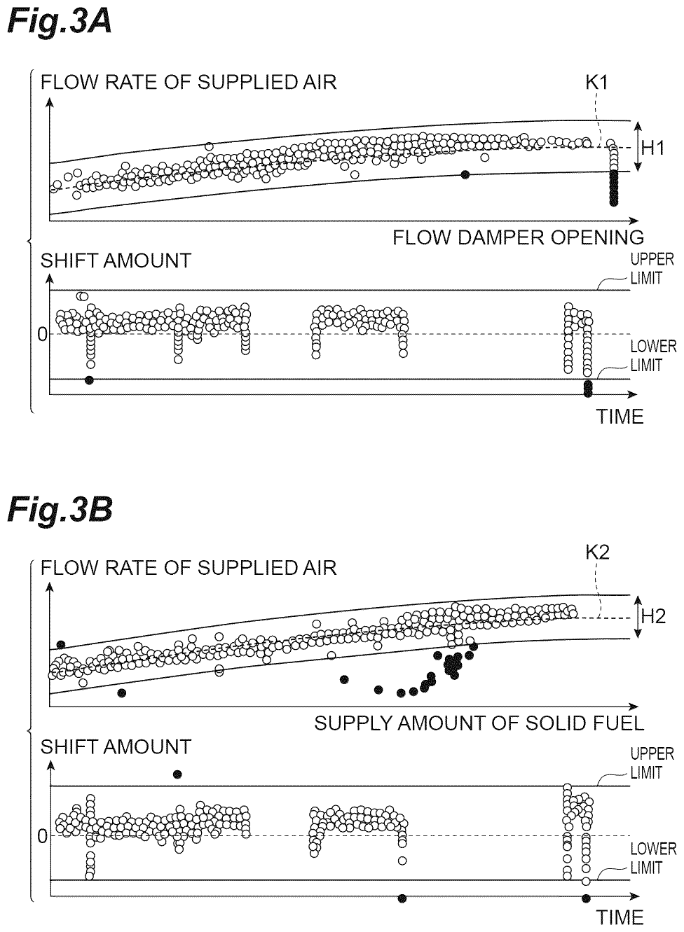

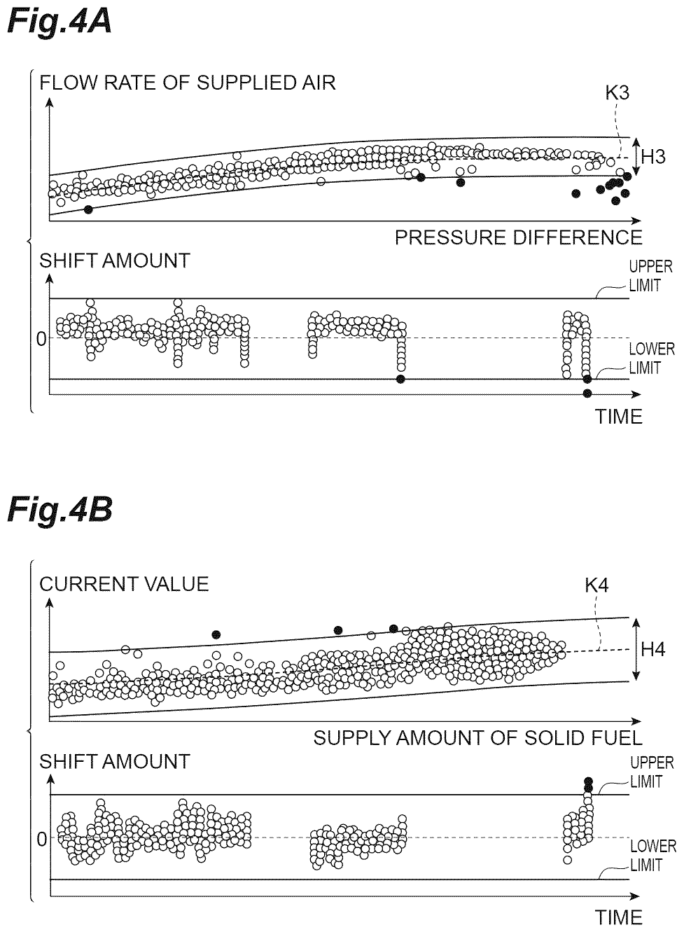

Here, an example of details of the pulverizer 10 will be described. As illustrated in FIG. 2, the pulverizer 10 pulverizes the solid fuel into powder form so that the solid fuel may be transported by being carried in an airflow. The pulverizer 10 includes a rotary table (movable portion) 101, mill rollers 102, an electric motor 103, a coal chute 104, and a pulverization ECU (Electronic Control Unit) 105. The rotary table 101 is installed in a lower part of a housing 100 of the pulverizer 10. The rotary table 101 is driven to rotate by the electric motor 103. The mill rollers 102 are installed so as to be pressed against an upper surface of the rotary table 101. The mill rollers 102 are rotated in accordance with rotation of the rotary table 101. For example, three mill rollers 102 are provided.

The coal chute 104 supplies the solid fuel transported from a storage bunker onto the rotary table 101. The solid fuel is supplied to a portion near the rotation center of the upper surface of the rotary table 101 via the coal chute 104. The solid fuel supplied onto the rotary table 101 is pulverized by being sandwiched between the upper surface of the rotary table 101 and the mill rollers 102. In this way, the rotary table 101 and the mill rollers 102 pulverize the supplied solid fuel into powder form.

An air supply pipe L1 that supplies air into the housing 100 is connected to a lower position of the housing 100. A flow damper D that controls a flow rate of supplied air supplied into the housing 100 is provided in the air supply pipe L1. A powder delivery pipe L2 that delivers powder of the pulverized solid fuel from the pulverizer 10 to the boiler 11 is connected to an upper position of the housing 100. The powder of the solid fuel pulverized by the rotary table 101 and the mill rollers 102 is carried by the airflow supplied from the air supply pipe L1 into the housing 100 and is delivered to the outside of the housing 100 from the powder delivery pipe L2.

The pulverization ECU 105 controls pulverization of solid fuel in the pulverizer 10. For example, the pulverization ECU 105 is an electronic control unit having a CPU (Central Processing Unit), a ROM (Read Only Memory), and a RAM (Random Access Memory) etc. The pulverization ECU 105 realizes various functions, for example, by loading a program recorded in the ROM into the RAM and executing the program loaded into the RAM by the CPU.

Here, the pulverization ECU 105 controls the electric motor 103 and the flow damper D so that a constant amount of powder of solid fuel is delivered from the pulverizer 10. For example, when the amount of delivered powder of solid fuel decreases, the pulverization ECU 105 controls the electric motor 103 so that a rotation speed of the rotary table 101 increases. Here, the pulverization ECU 105 increases a current value of power supplied to the electric motor 103 to increase the rotation speed of the rotary table 101. In addition, for example, when the amount of delivered powder of solid fuel decreases, the pulverization ECU 105 controls the flow damper D so that the opening of the flow damper D increases.

As illustrated in FIG. 1, the abnormality determination device 2 may acquire operation data of the pulverizer 10 by performing wired or wireless communication with the thermal power plant 1. The abnormality determination device 2 determines whether or not there is an abnormality in the pulverizer 10 provided in the thermal power plant 1 based on the operation data of the pulverizer 10. It should be noted that, “abnormality” here refers to a state in which solid fuel cannot be properly pulverized due to various reasons and an excessive amount of solid fuel accumulates (remains) in the pulverizer 10. In addition, “abnormality” here is not limited to occurrence of an abnormality, but also includes a sign of an abnormality. The abnormality determination device 2 is a server that supports maintenance of the thermal power plant 1, and may be configured using cloud computing.

The abnormality determination device 2 includes a determination ECU 20 and a presentation unit 30. The presentation unit 30 is a device that presents information to a supervisor (an operator), etc. of the thermal power plant 1. For example, the presentation unit 30 may include at least one of a monitor and a lamp that visually present information, and a speaker that outputs sound. Based on an instruction from the determination ECU 20, the presentation unit 30 presents information showing that an abnormality has occurred in the pulverizer 10 to a supervisor, etc. of the thermal power plant 1.

The determination ECU 20 is an electronic control unit having, for example, a CPU, a ROM, and a RAM, similarly to the pulverization ECU 105 of the pulverizer 10. The determination ECU 20 functionally includes a data acquisition unit 21, an index calculation unit 22, an abnormality determination unit 23, and a presentation control unit 24.

The data acquisition unit 21 acquires operation data indicating the operation state of the pulverizer 10 by communicating with the thermal power plant 1. The data acquisition unit 21 acquires a plurality of pieces of operation data indicating the operation state of the pulverizer 10. In this example, the data acquisition unit 21 acquires five pieces of operation data. Here, the data acquisition unit 21 acquires five pieces of operation data, namely, (1) flow rate of supplied air, (2) flow damper opening, (3) supply amount of solid fuel, (4) pressure difference, and (5) current value.

The (1) flow rate of supplied air is a flow rate of air supplied into the pulverizer 10 to deliver powder of solid fuel pulverized inside the pulverizer 10 out of the pulverizer 10 by an airflow. In other words, the (1) flow rate of supplied air is a flow rate of air supplied from the air supply pipe L1 into the housing 100. As the (1) flow rate of supplied air, for example, a detection value of an air flow rate sensor provided in the air supply pipe L1 may be used.

The (2) flow damper opening is the opening level of the flow damper D that controls the flow rate of the supplied air supplied into the housing 100 via the air supply pipe L1. For example, as the (2) flow damper opening, the control value used by the pulverization ECU 105 when controlling the opening of the flow damper D may be used.

The (3) supply amount of solid fuel is an amount of solid fuel supplied into the pulverizer 10 via the coal chute 104. As the (3) supply amount of solid fuel, a weight of solid fuel delivered from the storage bunker to the coal chute 104 per unit time may be used.

The (4) pressure difference is a pressure difference between pressure of supplied air and pressure of delivered air delivered from the pulverizer 10 to deliver powder of solid fuel. The pressure of the supplied air is the pressure of the air supplied from the air supply pipe L1 into the housing 100 of the pulverizer 10. For example, a detection value of an air pressure sensor provided in the air supply pipe L1 near a connection portion between the housing 100 and the air supply pipe L1 may be used as the pressure of the supplied air. In addition, the pressure of the delivered air delivered from the pulverizer 10 is the pressure of the air delivered from the housing 100 of the pulverizer 10 to the powder delivery pipe L2. For example, a detection value of an air pressure sensor provided in the powder delivery pipe L2 near a connection portion between the housing 100 and the powder delivery pipe L2 may be used as the pressure of the delivered air.

The (5) current value is a current value of power supplied to the electric motor 103 that drives and rotates the rotary table 101. For example, a detection value of a current sensor that detects the current value of the power supplied to the electric motor 103 may be used as the current value. In addition, the control value used when the pulverization ECU 105 controls the current value of the power supplied to the electric motor 103 may be used as the current value.

The index calculation unit 22 uses two mutually different pieces of operation data acquired by the data acquisition unit 21 to calculate an index indicating a correlation between these two pieces of operation data. The two mutually different pieces of operation data may be pieces of data of different types. In addition, the two mutually different pieces of operation data may be pieces of data acquired by different methods.

In this example, the index calculation unit 22 calculates four indices, namely, a first index, a second index, a third index, and a fourth index. A combination of two pieces of operation data used to calculate the first index, a combination of two pieces of operation data used to calculate the second index, a combination of two pieces of operation data used to calculate the third index, and a combination of two pieces of operation data used to calculate the fourth index are mutually different from each other.

For example, the index calculation unit 22 calculates, as the first index, an index indicating a correlation between the (1) flow rate of supplied air and the (2) flow damper opening. For example, as illustrated at the top portion of FIG. 3A, the first index is represented by the distribution diagram in which a vertical axis depicts the (1) flow rate of the supplied air and a horizontal axis depicts the (2) flow damper opening. For example, the index calculation unit 22 calculates, as the second index, an index indicating a correlation between the (1) flow rate of supplied air and the (3) supply amount of the solid fuel. For example, as illustrated at the top portion of FIG. 3B, the second index is represented by the distribution diagram in which a vertical axis depicts the (1) flow rate of the supplied air and a horizontal axis depicts the (3) supply amount of the solid fuel.

For example, the index calculation unit 22 calculates, as the third index, an index indicating a correlation between the (1) flow rate of supplied air and the (4) pressure difference. For example, as illustrated at the top portion of FIG. 4A, the third index is represented by the distribution diagram in which a vertical axis depicts the (1) flow rate of the supplied air and a horizontal axis depicts the (4) pressure difference. For example, the index calculation unit 22 calculates, as the fourth index, an index indicating a correlation between the (3) supply amount of the solid fuel and the (5) current value. For example, as illustrated at the top portion of FIG. 4B, the fourth index is represented by the distribution diagram in which a vertical axis depicts the (5) current value and a horizontal axis depicts the (3) supply amount of the solid fuel.

Here, a description of a state of each part will be given when an abnormality occurs in the pulverizer 10 illustrated in FIG. 2. The abnormality here refers to accumulation (remaining) of solid fuel inside the pulverizer 10. First, when an excessive amount of solid fuel beings to accumulate inside the pulverizer 10, a flow rate of delivered air delivered from the inside of the housing 100 of the pulverizer 10 via the powder delivery pipe L2 decreases. For this reason, a pressure difference between pressure of supplied air supplied to the pulverizer 10 and pressure of delivered air delivered from the pulverizer 10 increases.

When the pressure difference increases, the pulverization ECU 105 of the pulverizer 10 increases the opening of the flow damper D to increase the flow rate of the delivered air. In addition, the pulverization ECU 105 of the pulverizer 10 increases the rotation speed of the rotary table 101 to quickly pulverize the accumulated solid fuel. In other words, the pulverization ECU 105 increases the current value of power supplied to the electric motor 103. When the solid fuel further accumulates, the flow rate of the supplied air supplied into the housing 100 of the pulverizer 10 via the air supply pipe L1 decreases. In other words, when an abnormality occurs in the pulverizer 10, change occurs in the above-mentioned first to fourth indices.

As illustrated in FIG. 1, the abnormality determination unit 23 determines whether or not there is an abnormality in the pulverizer 10 based on the operation data acquired by the data acquisition unit 21. In this example, the abnormality determination unit 23 determines whether or not there is an abnormality in the pulverizer 10 based on an index indicating a correlation between pieces of operation data. Hereinafter, a description will be given of examples of the process of determining whether or not there is an abnormality in the abnormality determination unit 23.

### An Example

First, a description will be given of the an example of the process of determining whether or not there is an abnormality. The abnormality determination unit 23 determines whether or not an index falls outside a predetermined index range for each of a plurality of indices calculated by the index calculation unit 22. This index range is determined in advance for each index. This index range is a range that may be taken by the index when the operation state of the pulverizer 10 is a normal state.

For example, an index range H1 is predetermined for the first index illustrated at the top portion of FIG. 3A. The index range H1 is a range that may be taken by the first index when the operation state of the pulverizer 10 is the normal state. Similarly, an index range H2 is predetermined for the second index illustrated at the top portion of FIG. 3B. An index range H3 is predetermined for the third index illustrated at the top portion of FIG. 4A. An index range H4 is predetermined for the fourth index illustrated at the top portion of FIG. 4B. It should be noted that, in these figures, a case where a value of an index falls within a predetermined index range (that is, a case of the normal state) is indicated by a white circle, and a case where a value of an index is outside the predetermined index range (that is, a case of an abnormal state) is indicated by a black circle.

Then, the abnormality determination unit 23 determines that there is an abnormality in the pulverizer 10 when the number of indices out of the index range among a plurality of indices is greater than or equal to a predetermined reference number. A value less than or equal to the number of indices calculated by the index calculation unit 22 is set as the predetermined reference number. In addition, the predetermined reference number may be changed based on a state of solid fuel supplied to the pulverizer 10, an external environment, etc. For example, the abnormality determination unit 23 may determine that there is an abnormality in the pulverizer 10 when the number of indices out of the index range among the plurality of indices is greater than or equal to the reference number within a predetermined period of time.

### The Other Example

Next, a description will be given of the other example of the process of determining whether or not there is an abnormality. The abnormality determination unit 23 calculates a shift amount between a predetermined index reference value and each of a plurality of indices. The shift amount between the index reference value and the index refers to a difference between the index reference value and each value indicated by the index. The shift amount is calculated for each value indicated by the index. The index reference value is determined in advance for each index. As an example, a median of an index range that may be taken by the index when the operation state of the pulverizer 10 is the normal state is set as the index reference value. However, the index reference value is not limited thereto, and may be set to any value within the index range that may be taken by the index when the operation state of the pulverizer 10 is the normal state.

For example, an index reference value K1 is determined in advance for the distribution of the first index illustrated at the top portion of FIG. 3A. The index reference value K1 is set within the index range H1 that may be taken by the index when the operation state of the pulverizer 10 is the normal state. In addition, a bottom portion of FIG. 3A is time-series data of a shift amount when a vertical axis depicts a shift amount between the index reference value K1 and the first index and a horizontal axis depicts time. In the time-series data at the bottom portion of FIG. 3A, a “lower limit” of the shift amount corresponds to a lower limit of the index range H1 illustrated at the top portion of FIG. 3A, and an “upper limit” of the shift amount corresponds to an upper limit of the index range H1 illustrated at the top portion of FIG. 3A.

Similarly, an index reference value K2 is predetermined for the distribution of the second index illustrated at the top portion of FIG. 3B. A bottom portion of FIG. 3B is time-series data of a shift amount between the index reference value K2 and the second index. An index reference value K3 is predetermined for the distribution of the third index illustrated at the top portion of FIG. 4A. A bottom portion of FIG. 4A is time-series data of a shift amount between the index reference value K3 and the third index. An index reference value K4 is predetermined for the distribution of the fourth index illustrated at the top portion of FIG. 4B. A bottom portion of FIG. 4B is time-series data of a shift amount between the index reference value K4 and the fourth index.

Then, the abnormality determination unit 23 calculates an abnormality degree for each index based on the calculated shift amount. When the shift amount is large, the abnormality determination unit 23 increases the abnormality degree. It should be noted that as the rate (magnitude) of increase or decrease in the abnormality degree per unit shift amount, a different rate (magnitude) of increase or decrease for each index may be used by the abnormality determination unit 23.

Then, the abnormality determination unit 23 calculates a sum of a plurality of abnormality degrees calculated for each index. When the calculated sum exceeds a predetermined reference sum, the abnormality determination unit 23 determines that there is an abnormality in the pulverizer 10.

It should be noted that, when calculating the sum of the abnormality degrees, the abnormality determination unit 23 may calculate the sum of the abnormality degrees by weighting the abnormality degrees according to each index. Furthermore, the predetermined reference sum may be changed based on the state of the solid fuel supplied to the pulverizer 10, the external environment, etc.

When the abnormality determination unit 23 determines that there is an abnormality in the pulverizer 10, the presentation control unit 24 presents that there is an abnormality in the pulverizer 10 to the supervisor, etc. via the presentation unit 30. In this way, the supervisor, etc. may recognize that an abnormality has occurred in the pulverizer 10 without directly visually recognizing the inside of the pulverizer 10. In this way, the supervisor, etc. may perform maintenance work, etc. so that the abnormality in the pulverizer 10 is eliminated.

As described above, the abnormality determination unit 23 determines whether or not there is an abnormality based on the operation data of the pulverizer 10 in which changes in the state of the pulverizer 10 readily appear. In this way, the abnormality determination device 2 may more accurately determine whether or not there is an abnormality in the pulverizer 10 using the operation data of the pulverizer 10. As described above, since the abnormality determination device 2 may determine whether or not there is an abnormality, the supervisor, etc. of the thermal power plant 1 does not need to perform work of determining whether or not there is an abnormality in the pulverizer 10 based on various data.

The abnormality determination device 2 includes the index calculation unit 22 that calculates an index indicating a correlation between two mutually different pieces of operation data. As the example of a process of determining whether or not there is an abnormality, the abnormality determination unit 23 of the abnormality determination device 2 determines whether or not there is an abnormality based on whether or not the index falls outside a predetermined index range. In this case, the abnormality determination device 2 may accurately determine whether or not there is an abnormality in the pulverizer 10 using the index indicating the correlation between the two pieces of operation data.

As the example of the process of determining whether or not there is an abnormality, the abnormality determination unit 23 of the abnormality determination device 2 determines that there is an abnormality when the number of indices out of a predetermined index range is greater than or equal to a predetermined reference number. In this case, the abnormality determination device 2 may more accurately determine whether or not there is an abnormality in the pulverizer 10 using a plurality of indices each indicating a correlation between pieces of operation data.

As the other example of the process of determining whether or not there is an abnormality, the abnormality determination unit 23 of the abnormality determination device 2 calculates an abnormality degree for each of a plurality of indices. The abnormality determination unit 23 determines that there is an abnormality in the pulverizer 10 when a calculated sum of abnormality degrees exceeds a predetermined reference sum. In this case, the abnormality determination device 2 may more accurately determine whether or not there is an abnormality in the pulverizer 10 using a sum of abnormality degrees of a plurality of indices.

As the operation data of the pulverizer 10, the data acquisition unit 21 acquires the (1) flow rate of supplied air, the (2) flow damper opening, the (3) supply amount of solid fuel, the (4) pressure difference, and the (5) current value. The abnormality determination unit 23 determines whether or not there is an abnormality in the pulverizer 10 using an index calculated based on these pieces of operation data. In this way, the abnormality determination device 2 may determine whether or not there is an abnormality in the pulverizer 10 based on these pieces of operation data related to the pulverizer 10.

Even though the examples of the disclosure have been described above, the disclosure is not limited to the above-described examples. For example, the data acquisition unit 21 is not limited to acquiring five pieces of operation data, namely, the (1) flow rate of supplied air, the (2) flow damper opening, the (3) supply amount of solid fuel, the (4) pressure difference, and the (5) current value. The data acquisition unit 21 may acquire pieces of operation data, the number of which is other than five. In addition, the data acquisition unit 21 may acquire data other than the above-mentioned (1) flow rate of supplied air to (5) current value as the operation data of the pulverizer 10, so long as the data is related to operation of the pulverizer 10.

For example, the index calculation unit 22 is not limited to calculating four indices, namely, the first index to the fourth index. The index calculation unit 22 may calculate indices, the number of which is other than four. Furthermore, the index calculation unit 22 may calculate an index based on a combination of operation data other than a combination of operation data of the first index to the fourth index described above. The abnormality determination unit 23 is not limited to determining whether or not there is an abnormality using four indices. The abnormality determination unit 23 may determine whether or not there is an abnormality based on indices, the number of which is other than four, for example, by making a determination using only one index.

A pulverizer having a configuration other than that described with reference to FIG. 2 may be used as the pulverizer 10. Even in this case, the abnormality determination device 2 may determine whether or not there is an abnormality based on operation data of the pulverizer.

### SUPPLEMENTARY NOTE

Through this disclosure, it may be determined whether or not there is an abnormality in a pulverizer in a thermal power plant, and efficient operation of the thermal power plant may be achieved. For this reason, this disclosure contributes to the United Nations-led Sustainable Development Goals (SDGs).

Goal 7: “Ensure access to affordable, reliable, sustainable, and modern energy for all”.

1. A maintenance management system comprising:
a thermal power plant comprising a pulverizer and a boiler, wherein the pulverizer pulverizes solid fuel and supplies the pulverized solid fuel to the boiler; and
an abnormality determination device configured to determine whether or not there is an abnormality in the pulverizer,
wherein the abnormality determination device comprises at least one processor configured to:
acquire operation data indicating an operation state of the pulverizer; and
determine whether or not there is an abnormality in the pulverizer based on the acquired operation data.

2. A maintenance management system according to claim 1, wherein the abnormality determination device comprises a server that supports maintenance of the thermal power plant, and is configured using cloud computing.

3. A maintenance management system according to claim 1,
wherein the at least one processor further configured to calculate an index indicating a correlation between two mutually different pieces of the operation data acquired, and
wherein, when the calculated index is out of a predetermined index range, the at least one processor determines that there is an abnormality in the pulverizer.

4. A maintenance management system according to claim 1,
wherein the at least one processor further configured to calculate a plurality of indices each indicating a correlation between two mutually different pieces of the operation data acquired,
wherein the plurality of calculated indices are different from each other in terms of a combination of two pieces of the operation data used to calculate each index, and
wherein the at least one processor further configured to:
determine whether or not an index is out of an index range predetermined for each index for each of the plurality of indices, and
determine that there is an abnormality in the pulverizer when a number of indices out of the index range among the plurality of indices is greater than or equal to a predetermined reference number.

5. A maintenance management system according to claim 1,
wherein the at least one processor further configured to calculate a plurality of indices each indicating a correlation between two mutually different pieces of the operation data acquired,
wherein the plurality of calculated indices are different from each other in terms of a combination of two pieces of the operation data used to calculate each index, and
wherein the at least one processor further configured to:
calculate an abnormality degree based on a shift amount between an index reference value predetermined for each index and an index for each of the plurality of indices, and
determine that there is an abnormality in the pulverizer when a sum of a plurality of abnormality degrees each calculated for each index exceeds a predetermined reference sum.

6. A maintenance management system according to claim 1, wherein the operation data includes a flow rate of supplied air supplied into the pulverizer to deliver powder of the solid fuel pulverized in the pulverizer out of the pulverizer by an airflow.

7. A maintenance management system according to claim 6,
wherein the pulverizer comprises an air supply pipe and an air flow rate sensor provided in the air supply pipe, and
wherein the air flow rate sensor detects the flow rate of the supplied air.

8. A maintenance management system according to claim 6, wherein the operation data includes an opening level of a flow damper configured to control the flow rate of the supplied air.

9. A maintenance management system according to claim 8,
wherein the pulverizer comprises a pulverization ECU (Electronic Control Unit), and
wherein a control value used by the pulverization ECU when the pulverization ECU controls the flow damper is utilized as the opening level of a flow damper.

10. A maintenance management system according to claim 6, wherein the operation data includes a pressure difference between pressure of the supplied air and pressure of delivered air delivered from the pulverizer to deliver the powder by an airflow.

11. A maintenance management system according to claim 10,
wherein the pulverizer comprises a first air pressure sensor provided in an air supply pipe and a second air pressure sensor provided in a powder delivery pipe, and
wherein the first air pressure sensor detects the pressure of the supplied air and the second air pressure sensor detects the pressure of the delivered air.

12. A maintenance management system according to claim 1, wherein the operation data includes a supply amount of the solid fuel supplied to the pulverizer.

13. A maintenance management system according to claim 12,
wherein the pulverizer comprises a storage bunker and a coal chute, and
wherein a weight of the solid fuel delivered from the storage bunker to the coal chute per unit time is utilized as the supply amount of the solid fuel.

14. A maintenance management system according to claim 1, wherein the operation data includes a current value of power supplied to an electric motor configured to drive a movable portion installed in the pulverizer to pulverize the solid fuel.

15. A maintenance management system according to claim 14,
wherein the pulverizer comprises a current sensor, and
wherein the current sensor detects the current value of the power supplied to an electric motor.

16. A maintenance management system according to claim 1, wherein the abnormality determination device further comprises a monitor that visually presents information to an operator of the thermal power plant.

17. A maintenance management system according to claim 1, wherein the abnormality determination device further comprises a lamp that visually presents information to an operator of the thermal power plant.

18. A maintenance management system according to claim 1, wherein the abnormality determination device further comprises a speaker that auditorily presents information to an operator of the thermal power plant.

19. An abnormality determination device configured to determine whether or not there is an abnormality in a pulverizer that pulverizes solid fuel and supplies the pulverized solid fuel to a boiler of a thermal power plant, the abnormality determination device comprising at least one processor configured to:
acquire operation data indicating an operation state of the pulverizer; and
determine whether or not there is an abnormality in the pulverizer based on the acquired operation data.

20. An abnormality determination device configured to determine whether or not there is an abnormality in a pulverizer that pulverizes solid fuel and supplies the pulverized solid fuel to a boiler of a thermal power plant, the abnormality determination device comprising:
a data acquisition unit configured to acquire operation data indicating an operation state of the pulverizer; and
an abnormality determination unit configured to determine whether or not there is an abnormality in the pulverizer based on the acquired operation data.
